(19) United States
(12) Patent Application Publication
(10) Pub. No.: US 2025/0391751 A1
(43) Pub. Date: Dec. 25, 2025

(54) PRINTED CIRCUIT BOARD AND SEMICONDUCTOR PACKAGE INCLUDING THE SAME

(71) Applicant: Samsung Electronics Co., Ltd., Suwon-si (KR)

(72) Inventors: Hyuna Lee, Suwon-si (KR); Jaeseok Jang, Suwon-si (KR); Taeyeong Kim, Suwon-si (KR); Jaekwang Lee, Suwon-si (KR); Dongmin Jang, Suwon-si (KR)

(21) Appl. No.: 19/024,231

(22) Filed: Jan. 16, 2025

(30) Foreign Application Priority Data
Jun. 19, 2024 (KR) 10-2024-0079800

(51) Int. Cl. H01L 23/498; H01L 21/48; H05K 1/11

(52) U.S. Cl. CPC H01L 23/49811; H01L 21/4867; H01L 23/49866; H05K 1/111; H05K 2201/10189

(57) ABSTRACT

A printed circuit board includes a body including a wiring pattern and an insulating layer at least partially surrounding the wiring pattern and a connector on a lower surface of the body, wherein the connector includes a lower pad located on the lower surface of the body, and a plurality of protective layers on the lower pad where one of the protective layers comprises solder.

### CROSS-REFERENCE TO RELATED APPLICATION

This application is based on and claims priority under 35 U.S.C. § 119 to Korean Patent Application No. 10-2024-0079800, filed on Jun. 19, 2024, in the Korean Intellectual Property Office, the disclosure of which is incorporated by reference herein in its entirety.

### BACKGROUND

Embodiments of the inventive concept relate to a printed circuit board and a semiconductor package including the printed circuit board, and more particularly, to a printed circuit board having improved corrosion reliability of a lower pad thereof and a semiconductor package including the printed circuit board.

For surface treatment of printed circuit boards (PCBs), semi-additive processes, such as electroless nickel immersion gold (ENIG) surface treatment and electroless nickel electroless palladium immersion gold (ENEPIG) surface treatment have been widely used. However, because it may be difficult for protective layers formed by the ENIG method and ENEPIG method to have thicknesses greater than certain thickness thresholds, hyper-corrosion or black pad may occur in surfaces of metal pads.

Also, regarding PCBs for recently used compression attached memory modules (CAMMs), the surfaces of the PCBs, on which pads are formed, and socket pins of a motherboard are brought into contact with and fastened to each other in a vertical direction by a compression attach method. Accordingly, the surface treatment of PCBs is becoming increasingly important. Accordingly, research is continuing on the surface treatment of pads, which are connected to a motherboard, of the PCB.

### SUMMARY

Embodiments of the inventive concept provide a printed circuit board having improved reliability of lower pads connected to a motherboard and a semiconductor package including the printed circuit board.

Also, the objects of the inventive concept are not limited to the aforementioned object, but other objects not described herein will be clearly understood by those skilled in the art from the following description.

According to an aspect of the inventive concept, there is provided a printed circuit board.

The printed circuit board includes a body including a wiring pattern and an insulating layer at least partially surrounding the wiring pattern and a connector located on a lower surface of the body, wherein the connector includes a lower pad located on the lower surface of the body, and a plurality of protective layers on the lower pad where one of the protective layers includes solder.

The printed circuit board includes a body including a wiring pattern and an insulating layer configured to at least partially cover the wiring pattern and a connector on a lower surface of the body, wherein the connector includes a lower pad on the lower surface of the body, a first protective layer on the lower pad and including nickel, and a second protective layer on the first protective layer, wherein the second protective layer is formed by a screen printing process, and wherein a thickness of the second protective layer in a first direction is greater than a thickness of the first protective layer in the first direction, the first direction being perpendicular to the lower surface of the body.

According to another aspect of the inventive concept, there is provided a semiconductor package.

The semiconductor package includes a body including a wiring pattern, an insulating layer at least partially surrounding the wiring pattern, and a hole extending through the body in a first direction from an upper surface of the body to a lower surface of the body, a connector on the lower surface of the body, an upper pad on the upper surface of the body, and a semiconductor chip electrically connected to the body via the upper pad, wherein the connector includes a lower pad on the lower surface of the body, a first protective layer on the lower pad, a second protective layer on the first protective layer, and a third protective layer located on the second protective layer, wherein the first protective layer includes nickel and is formed by an electroless plating process, wherein the second protective layer includes silver, wherein the third protective layer is formed by a screen printing process, wherein the third protective layer includes at least one of solder and silver, wherein a thickness of the third protective layer is greater than a thickness of the first protective layer, and wherein the thickness of the third protective layer in the first direction is in a range from about 50 μm to about 100 μm.

### BRIEF DESCRIPTION OF THE DRAWINGS

Embodiments will be more clearly understood from the following detailed description taken in conjunction with the accompanying drawings in which:

FIG. 1 is a perspective view showing an electronic device according to some embodiments;

FIG. 2A is a plan view schematically showing a first semiconductor package of FIG. 1;

FIG. 2B is a bottom view schematically showing the first semiconductor package of FIG. 1;

FIG. 3 is a cross-sectional view of the semiconductor package taken along line A1-Al' of FIG. 2B;

FIGS. 4A and 4B show embodiments of enlarged views of region AA of FIG. 3;

FIGS. 5A and 5B show embodiments of enlarged views of region AA of FIG. 3;

FIGS. 6A and 6B show embodiments of enlarged views of region AA of FIG. 3;

FIGS. 7 to 12 are enlarged views illustrating a method of manufacturing a connector of a printed circuit board, according to an embodiment; and

FIGS. 13 to 17 are enlarged views illustrating a method of manufacturing a connector of a printed circuit board, according to an embodiment.

### DETAILED DESCRIPTION OF THE EMBODIMENTS

Hereinafter, example embodiments are described in detail with reference to the accompanying drawings. The same reference numerals are given to the same elements in the drawings, and repeated descriptions thereof are omitted. The same reference numerals are used for the same components in the drawings, and duplicate descriptions for the same components are omitted. As used herein, the term “and/or” includes any and all combinations of one or more of the associated listed items. It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure. It is noted that aspects described with respect to one embodiment may be incorporated in different embodiments although not specifically described relative thereto. That is, all embodiments and/or features of any embodiments can be combined in any way and/or combination.

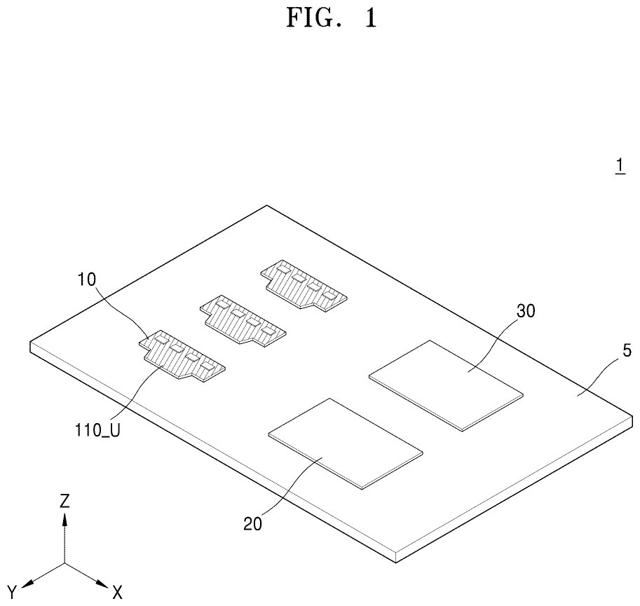

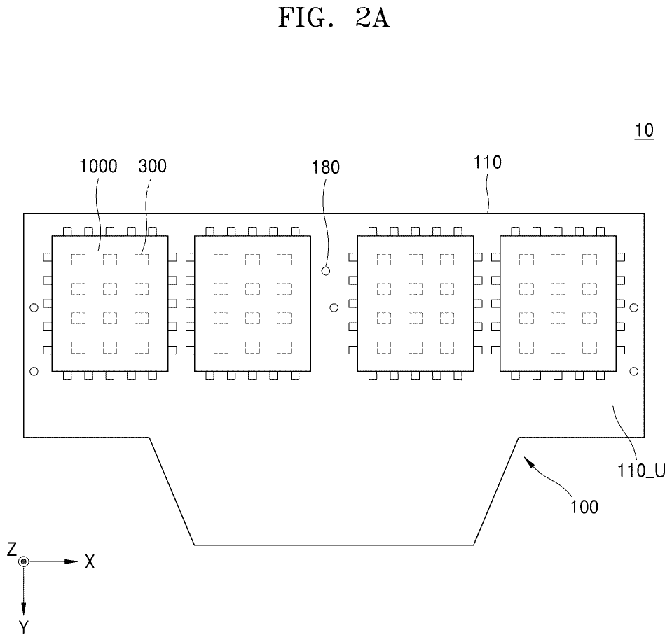

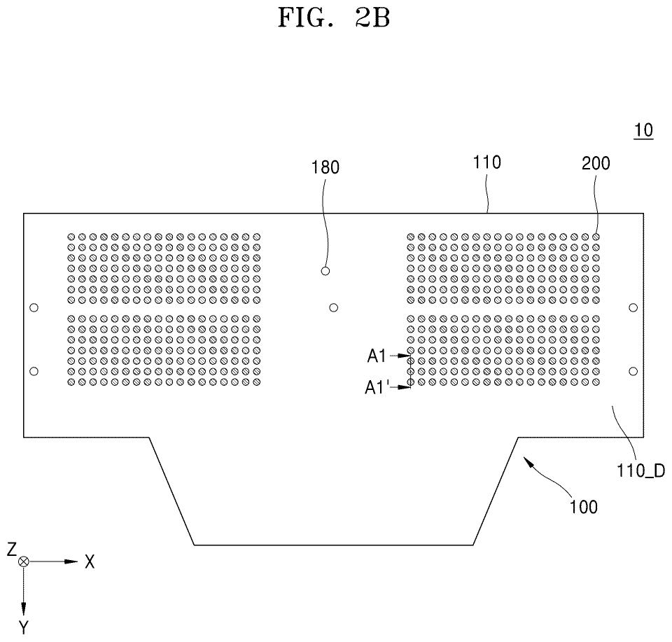

FIG. 1 is a perspective view showing an electronic device 1 according to some embodiments. FIG. 2A is a plan view schematically showing a semiconductor package of FIG. 1. FIG. 2B is a bottom view schematically showing the semiconductor package of FIG. 1.

Referring to FIGS. 1, 2A, and 2B, the electronic device 1 may include a motherboard 5, a first semiconductor package 10, a second semiconductor package 20, and a third semiconductor package 30.

As shown in FIG. 1, the motherboard 5 may include a substrate having an upper surface on which the first to third semiconductor packages 10, 20, and 30 are mounted. For example, the first semiconductor package 10, the second semiconductor package 20, and the third semiconductor package 30 may be mounted on the motherboard 5. Herein, the first semiconductor package 10, the second semiconductor package 20, and the third semiconductor package 30 may be different types of packages. Although FIG. 1 illustrates that the first to third semiconductor packages 10, 20, and 30 are mounted on the motherboard 5, the number and types of semiconductor packages 10, 20, and 30 mounted on the motherboard 5 are not limited thereto. One type of semiconductor package, two types of semiconductor packages, or four or more types of semiconductor packages may be mounted on the motherboard 5. The motherboard 5 may also be understood as a mainboard, a main circuit board, a base board, a planar board, or a system board.

In the following diagrams, an X-axis direction and a Y-axis direction represent directions parallel to the surface of the motherboard 5, on which the first to third semiconductor packages 10, 20, and 30 are mounted, and the X-axis direction and the Y-axis direction may be understood as directions perpendicular to each other. A Z-axis direction may represent a direction perpendicular to the upper or lower surface of the motherboard 5, that is, a direction perpendicular to the X-Y plane. Also, in the following drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The first semiconductor package 10 may include a module that is mounted on the motherboard 5 by a compression attachment method. According to some embodiments, the first semiconductor package 10 may include a memory module that is mounted on the motherboard 5 by the compression attachment method. In some embodiments, the first semiconductor package 10 may include a compression attached memory module (CAMM) or a low power compression attached memory module (LPCAMM). However, the type of the first semiconductor package 10 is not limited thereto. The first semiconductor package 10 may include any module that is mounted on the motherboard 5 by the compression attachment method or any module for which it is difficult to apply electrolytic plating to a connector 200 (FIG. 2B) connected to the motherboard 5.

The second semiconductor package 20 may be a graphics module mounted on the motherboard 5. For example, the second semiconductor package 20 may include a graphics processing unit (GPU). The third semiconductor package 30 may be a central processing module mounted on the motherboard 5. For example, the third semiconductor package 30 may include a central processing unit (CPU). However, the second semiconductor package 20 and the third semiconductor package 30 are not limited thereto, and the second semiconductor package 20 and the third semiconductor package 30 may include any type of semiconductor package mounted on the motherboard 5.

The first semiconductor package 10 may include a body 110 and a semiconductor chip 1000. The body 110 may include a substrate on which the semiconductor chip 1000 is mounted, and at least one semiconductor chip 1000 may be mounted on an upper surface 110_U of the body 110. According to some embodiments, four semiconductor chips 1000 may be mounted on the upper surface 110_U of the body 110. However, the number of semiconductor chips 1000 mounted on the upper surface 110_U of the body 110 is not limited thereto, and a single semiconductor chip 1000 or a plurality of semiconductor chips 1000 may be mounted on the upper surface 110_U of the body 110.

An upper pad 300 may be disposed on the upper surface of the body 110. According to some embodiments, a plurality of upper pads 300 may be provided. The semiconductor chip 1000 mounted on the upper surface 110_U of the body 110 may be electrically connected to the body 110 via the upper pad 300.

According to some embodiments, the semiconductor chip 1000 mounted on the upper surface 110_U of the body 110 may include a memory chip. The memory chip may include, for example, volatile memory chips, such as dynamic random-access memory (DRAM) and static random-access memory (SRAM), or non-volatile memory chips, such as phase-change random-access memory (PRAM), magnetoresistive random-access memory (MRAM), ferroelectric random-access memory (FeRAM), and resistive random-access memory (RRAM). In some embodiments, the semiconductor chip 1000 mounted on the upper surface of the body 110 may include a logic chip. The logic chip may include, for example, microprocessors, such as a CPU, a GPU, and an application processor (AP), analog devices, or digital signal processors.

Also, in some embodiments, a plurality of semiconductor chips 1000 may be mounted on the upper surface of the body 110, and at least one of the plurality of semiconductor chips 1000 may include a different type of chip. For example, at least one of the plurality of semiconductor chips 1000 may include a memory chip and another may include a logic chip.

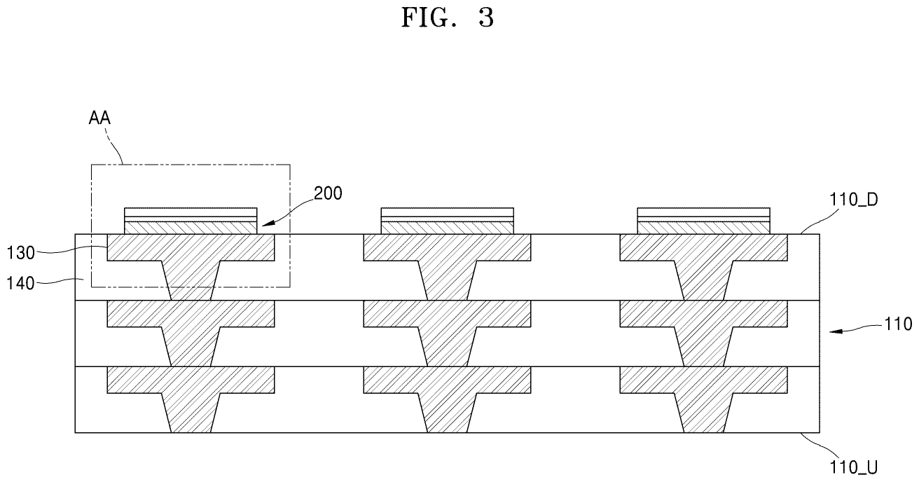

A connector 200 may be located on a lower surface 110_D of the body 110. According to some embodiments, a plurality of connectors 200 may be formed on the lower surface 110_D of the body 110. The plurality of connectors 200 may be spaced apart from each other in the first and second horizontal directions X and Y. The connector 200 may serve as a passage for electrically connecting the first semiconductor package 10 to the motherboard 5. The first semiconductor package 10 may be connected to the motherboard 5 via the connector 200. The first semiconductor package 10 may be mounted on the upper surface of the motherboard 5 via the connector 200 formed on the lower surface 110_D of the body 110. The connector 200 is described below in detail with reference to FIG. 3.

According to some embodiments, when viewed from above in the vertical direction Z, i.e., a plan view, the body 110 may have a shape in which a rectangle and a trapezoid are joined to each other in the second horizontal direction Y, as shown in FIGS. 2A and 2B. For example, when viewed from above in the vertical direction Z, the body 110 may have a shape that includes a rectangle extending in the first horizontal direction X and a protrusion protruding in the second horizontal direction Y from one side surface of the rectangle. Herein, the protrusion in the Y direction may have a shape of which the width is reduced with increasing distance from the rectangle as shown in FIG. 2A. However, the shape of the body 110 is not limited thereto.

The body 110 may include a hole 180 passing through the body 110 in the vertical direction Z from the upper surface 110_U to the lower surface 110_D of the body 110. The hole 180 may be a hole into which a screw is inserted. According to some embodiments, the first semiconductor package 10 and the motherboard 5 may be coupled to each other by a screw. Herein, an external screw is inserted into the hole 180 of the body 110, and the first semiconductor package 10 and the motherboard 5 may be screw-coupled to each other by an internal screw connected to the external screw.

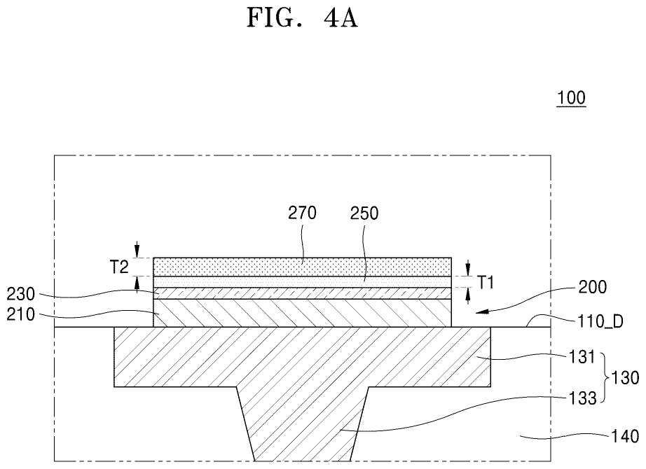

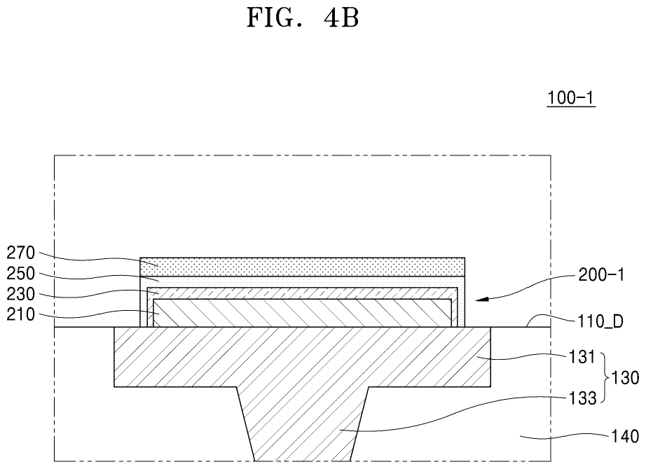

According to the related art, a motherboard 5 and a printed circuit board 100 are connected to each other by a compression attachment method. In this case, to prevent corrosion of a lower pad 210 (FIG. 4A) of the printed circuit board 100 that comes into contact with the motherboard 5, a protective layer is formed on the surface of the lower pad 210 by an electroless plating process. However, in the electroless plating process, the protective layer may not be formed to a certain thickness or more, and thus, the risk of corrosion of the lower pad 210 increases. Specifically, when forming a protective layer by an electroless plating process, such as electroless nickel-immersion gold (ENIG), the thickness of the protective layer is in a range from about 0.03 μm to about 0.05 μm. Therefore, it is difficult to compensate for the corrosion vulnerability of the lower pad 210.

Accordingly, in a printed circuit board 100 according to the inventive concept, a protective layer is formed by a screen printing method as described below with reference to FIG. 3. As a result, the protective layer may have a certain thickness or more and thus prevent or inhibit corrosion of a lower pad 210.

FIG. 3 is a cross-sectional view of the first semiconductor package 10 taken along line A1-A1′ of FIG. 2B. FIGS. 4A and 4B show embodiments of enlarged views of region AA of FIG. 3. Hereinafter, repeated descriptions of those features given with reference to FIGS. 1, 2A, and 2B are omitted, and the description focuses on the differences in the embodiments.

First, referring to FIG. 3, a wiring pattern 130 and an insulating layer 140 at least partially surrounding the wiring pattern 130 may be formed inside the body 110 of the printed circuit board 100. According to some embodiments, the wiring pattern 130 may include a wiring line pattern 131 and a wiring via pattern 133. The wiring line pattern 131 may have a shape that extends in a horizontal direction along at least one of the upper surface and the lower surface of each of the plurality of insulating layers 140 stacked in the vertical direction Z. The wiring via pattern 133 may have a shape that extends through the insulating layer 140 in the vertical direction Z. The wiring via pattern 133 may electrically connect wiring line patterns 131 located at different vertical levels. In some embodiments, at least some of the wiring line patterns 131 may be formed integrally with some of the wiring via patterns 133. According to some embodiments, the wiring pattern 130 may include copper, nickel, stainless steel, and/or beryllium copper.

The insulating layer 140 may be provided as a plurality of layers that are stacked on each other in the vertical direction Z. According to some embodiments, the insulating layer 140 may include at least one material selected from a group consisting of phenolic resin, epoxy resin, and polyimide. The insulating layer 140 may include, for example, at least one material selected from a group consisting of flame retardant 4 (FR-4), tetrafunctional epoxy, polyphenylene ether, epoxy/polyphenylene oxide, bismaleimide triazine (BT), Thermount, cyanate ester, polyimide, and liquid crystal polymer.

Each of connectors 200 and 200-1 may be located on the lower surface 110_D of the body 110. The connectors 200 and 200-1 may serve as a passage for connection to the motherboard 5 (see FIG. 1). According to some embodiments, the connectors 200 and 200-1 may each include a lower pad 210, a first protective layer 230, a second protective layer 250, and a third protective layer 270, as shown in FIG. 4A and FIG. 4B. The lower pad 210 may be located on the lower surface 110_D of the body 110 and electrically connected to the wiring pattern 130 formed inside the body 110. According to some embodiments, the lower pad 210 may include copper (Cu).

The first protective layer 230 may be located on the lower pad 210. According to some embodiments, the first protective layer 230 may completely cover the upper surface of the lower pad 210 as shown in FIG. 4A. The upper surface of the lower pad 210 may be opposite to the lower surface of the lower pad 210, and the lower surface of the lower pad 210 may be a surface of the lower pad 210, which is in contact with the lower surface 110_D of the body 110. Similarly, the upper surface of the lower pad 210 may be opposite to the lower surface of the lower pad 210 that is in contact with the lower surface 110_D of the body 110. According to some embodiments, the first protective layer 230 may include nickel (Ni). The first protective layer 230 may be formed by an electroless plating process. The electroless plating process may include, for example, an ENIG method.

In some embodiments, the first protective layer 230 may be on and cover only the upper surface of the lower pad 210 and may not cover or be on side surfaces of the lower pad 210, as shown in FIG. 4A. That is, the side surfaces of the lower pad 210 may, in some embodiments, be free of the first protective layer 230. In other embodiments, the first protective layer 230 may be on and cover the side surfaces of the lower pad 210 as shown in FIG. 4B. That is, the first protective layer 230 may be on and cover the upper surface and side surfaces of the lower pad 210. When the first protective layer 230 is formed by the electroless plating process, the first protective layer 230 may be formed on all exposed surfaces of the lower pad 210 as shown in FIG. 4B.

The second protective layer 250 may be located on the first protective layer 230. According to embodiments, the second protective layer 250 may completely cover the upper surface of the first protective layer 230. The upper surface of the first protective layer 230 may be opposite to the lower surface of the first protective layer 230. Also, the lower surface of the first protective layer 230 may be a surface of the first protective layer 230, which is in contact with the lower pad 210. According to embodiments, the second protective layer 250 may include gold (Au). The second protective layer 250 may be formed by an electroless plating process. The electroless plating process may include, for example, an ENIG method.

In some embodiments, the second protective layer 250 may be on and cover only the upper surface of the first protective layer 230 and may not be on or cover side surfaces of the first protective layer 230, as shown in FIG. 4A. That is, the side surfaces of the first protective layer 230 may, in some embodiments, be free of the second protective layer 250. In other embodiments, the second protective layer 250 may be on and cover the side surfaces of the first protective layer 230, as shown in FIG. 4B. That is, the second protective layer 250 may be on and cover the upper surface and side surfaces of the first protective layer 230. When the second protective layer 250 is formed by an ENIG method, the second protective layer 250 may be formed on all exposed surfaces of the first protective layer 230, as shown in FIG. 4B.

The third protective layer 270 may be located on the second protective layer 250. According to some embodiments, the third protective layer 270 may completely cover the upper surface of the second protective layer 250. The upper surface of the second protective layer 250 may be opposite to the lower surface of the second protective layer 250. Also, the lower surface of the second protective layer 250 may be a surface of the second protective layer 250, which is in contact with the first protective layer 230. According to some embodiments, the third protective layer 270 may be formed by the screen printing process. The screen printing process may include, for example, a screen printing method using a stencil mask. According to some embodiments, the third protective layer 270 may include solder or silver (Ag). Because the third protective layer 270 is formed by the screen printing process, the third protective layer 270 may be on and cover only the upper surface of the second protective layer 250 and may not be on or cover side surfaces of the second protective layer 250, as shown in FIGS. 4A and 4B. That is, the side surfaces of the second protective layer 250 may, in some embodiments, be free of the third protective layer 270. In some embodiments, the third protective layer 270 may not be on or cover at least a portion of a side surface of the second protective layer 250. In this case, the third protective layer 270 may be on and partially cover the side surfaces of the second protective layer 250 but not completely cover the side surfaces of the second protective layer 250.

A thickness T2, in the vertical direction Z, of the third protective layer 270 formed by the screen printing process may be greater than a thickness T1, in the vertical direction Z, of the second protective layer 250 formed by the electroless plating process. For example, the thickness T1 of the second protective layer 250 formed by the electroless plating process may be in a range from about 0.03 μm to about 0.05 μm, and the thickness T2 of the third protective layer 270 formed by the screen printing process may be in a range from about 50 μm to about 100 μm.

Each of printed circuit boards 100 and 100-1 according to embodiments of the inventive concept may further include the third protective layer 270 formed by the screen printing process in addition to the first protective layer 230, which is on and at least partially covers the lower pad 210, and the second protective layer 250. Because the third protective layer 270 is formed by the screen printing process, the third protective layer 270 may have an increased thickness. Accordingly, the printed circuit boards 100 and 100-1 according to embodiments of the inventive concept may not only have multiple protective layers, e.g., three protective layers, but also increase the thickness of the third protective layer 270 formed on the outermost side from the lower pad 210, thereby effectively preventing or reducing the risk of the lower pad 210 from being corroded.

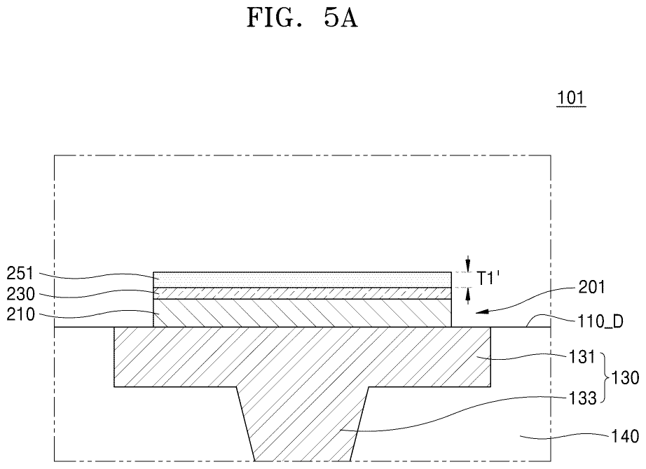

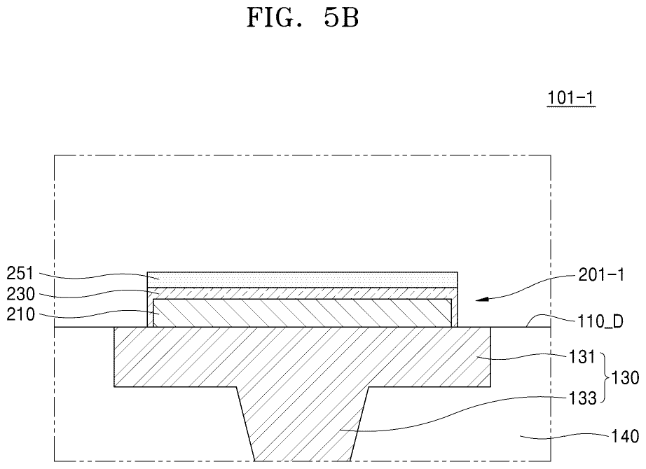

FIGS. 5A and 5B show embodiments of enlarged views of region AA of FIG. 3. Hereinafter, repeated descriptions of features given with reference to FIGS. 1, 2A, 2B, 3, 4A, and 4B are omitted, and the description focuses on the differences in the embodiments.

Referring to FIGS. 3, 5A, and 5B, printed circuit boards 101 and 101-1 may include a body 110 and connectors 201 and 201-1, respectively. A wiring pattern 130 and an insulating layer 140 at least partially surrounding the wiring pattern 130 may be formed inside the body 110. According to some embodiments, the wiring pattern 130 may include a wiring line pattern 131 and a wiring via pattern 133. Each of the connectors 201 and 201-1 may be located on a lower surface 110_D of the body 110. According to some embodiments, the connectors 201 and 201-1 may each include a lower pad 210, a first protective layer 230, and a second protective layer 251, as shown in FIGS. 5A and 5B.

The lower pad 210 may be located on the lower surface 110_D of the body 110 and electrically connected to the wiring pattern 130 formed inside the body 110. According to some embodiments, the lower pad 210 may include copper (Cu).

The first protective layer 230 may be located on the lower pad 210. According to some embodiments, the first protective layer 230 may be on and completely cover the upper surface of the lower pad 210. The upper surface of the lower pad 210 may be opposite to the lower surface of the lower pad 210, and the lower surface of the lower pad 210 may be a surface of the lower pad 210, which is in contact with the lower surface 110_D of the body 110. According to some embodiments, the first protective layer 230 may include nickel (Ni). The first protective layer 230 may be formed by an electroless plating process.

In some embodiments, the first protective layer 230 may be on and cover only the upper surface of the lower pad 210 but not be on or cover side surfaces of the lower pad 210, as shown in FIG. 5A. That is, the side surfaces of the lower pad 210 may, in some embodiments, be free of the first protective layer 230. Also, in some embodiments, the first protective layer 230 may be on and cover the side surfaces of the lower pad 210, as shown in FIG. 5B. That is, the first protective layer 230 may be on and cover the upper surface and side surfaces of the lower pad 210. When the first protective layer 230 is formed by the electroless plating process, the first protective layer 230 may be formed on all exposed surfaces of the lower pad 210, as shown in FIG. 5B.

The second protective layer 251 may be located on the first protective layer 230. According to embodiments, the second protective layer 251 may be on and completely cover the upper surface of the first protective layer 230. The upper surface of the first protective layer 230 may be opposite to the lower surface of the first protective layer 230. The lower surface of the first protective layer 230 may be a surface of the first protective layer 230, which is in contact with the lower pad 210. According to some embodiments, the second protective layer 251 may be formed by a screen printing process. According to some embodiments, the second protective layer 251 may include at least one of gold (Au) and silver (Ag).

A thickness T1′ of the second protective layer 251 formed by the screen printing process may be greater than the thickness T1 of the second protective layer 250 formed by the electroless plating process as described with reference to FIG. 4A and FIG. 4B. According to some embodiments, the thickness of the second protective layer 251 may be in a range from about 50 μm to about 100 μm. Also, the second protective layer 251 formed by the screen printing process may be on and cover only the upper surface of the first protective layer 230 and may not be on or cover the side surfaces of the first protective layer 230. That is, the side surfaces of the first protective layer may, in some embodiments, be free of the second protective layer 251. In some embodiments, the second protective layer 251 may be on and cover the upper surface of the first protective layer 230 and may be on and cover at least a portion of the side surfaces of the first protective layer 230.

In the printed circuit boards 101 and 101-1 according to embodiments of the inventive concept, the first protective layer 230 on and at least partially covering the lower pad 210 may be formed by the electroless plating process, and the second protective layer 251 on and at least partially covering the first protective layer 230 may be formed by the screen printing process. Accordingly, the thickness of the second protective layer 251 may increase, thus effectively preventing or inhibiting the lower pad 210 from being corroded. In addition, the printed circuit boards 101 and 101-1 have a smaller number of protective layers than the printed circuit boards 100 and 100-1 described with reference to in FIGS. 4A and 4B. Accordingly, the time and cost required for the processes may be reduced.

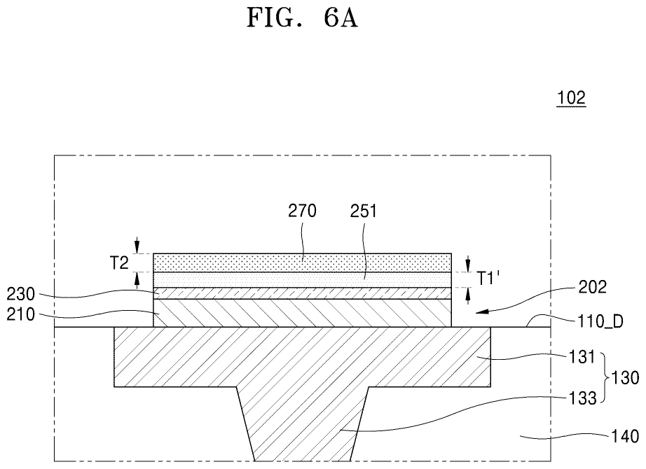

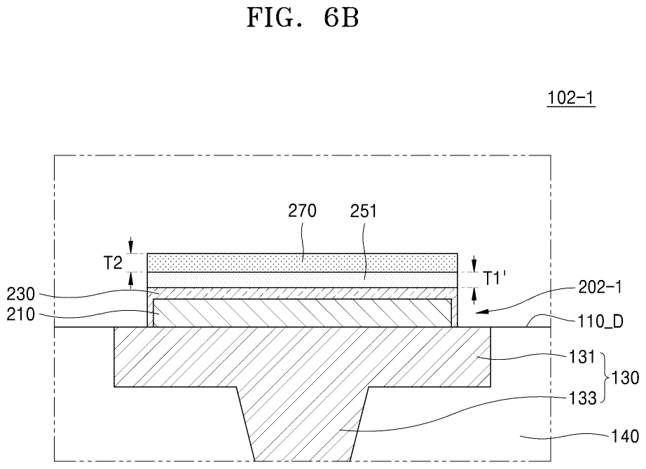

FIGS. 6A and 6B show embodiments of enlarged views of region AA of FIG. 3. Hereinafter, repeated descriptions as those given with reference to FIGS. 1, 2A, 2B, 3, 4A, 4B, 5A, and 5B are omitted, and the description focuses on the differences.

Referring to FIGS. 3, 6A, and 6B, printed circuit boards 102 and 102-1 may include a body 110 and connectors 202 and 202-1, respectively. A wiring pattern 130 and an insulating layer 140 at least partially surrounding the wiring pattern 130 may be formed inside the body 110. According to some embodiments, the wiring pattern 130 may include a wiring line pattern 131 and a wiring via pattern 133. Each of the connectors 202 and 202-1 may be located on a lower surface 110_D of the body 110. According to some embodiments, the connectors 202 and 202-1 may each include a lower pad 210, a first protective layer 230, a second protective layer 251, and a third protective layer 270, as shown in FIG. 6A and FIG. 6B.

The lower pad 210 may be located on the lower surface 110_D of the body 110 and electrically connected to the wiring pattern 130 formed inside the body 110. According to some embodiments, the lower pad 210 may include copper (Cu).

The first protective layer 230 may be located on the lower pad 210. According to embodiments, the first protective layer 230 may be on and completely cover the upper surface of the lower pad 210. The upper surface of the lower pad 210 may be opposite to the lower surface of the lower pad 210, and the lower surface of the lower pad 210 may be a surface of the lower pad 210, which is in contact with the lower surface 110_D of the body 110. According to some embodiments, the first protective layer 230 may include nickel (Ni). The first protective layer 230 may be formed by an electroless plating process.

In some embodiments, the first protective layer 230 may be on and cover only the upper surface of the lower pad 210 and may not be on or cover side surfaces of the lower pad 210, as shown in FIG. 6A. That is, the side surfaces of the lower pad 210 may, in some embodiments, be free of the first protective layer 230. Also, in some embodiments, the first protective layer 230 may be on and cover the side surfaces of the lower pad 210, as shown in FIG. 6B. That is, the first protective layer 230 may be on and cover the upper surface and side surfaces of the lower pad 210. When the first protective layer 230 is formed by the electroless plating process, the first protective layer 230 may be formed on all exposed surfaces of the lower pad 210, as shown in FIG. 6B.

The second protective layer 251 may be located on the first protective layer 230. According to some embodiments, the second protective layer 251 may be on and completely cover the upper surface of the first protective layer 230. The upper surface of the first protective layer 230 may be opposite to the lower surface of the first protective layer 230. The lower surface of the first protective layer 230 may be a surface of the first protective layer 230, which is in contact with the lower pad 210. According to some embodiments, the second protective layer 251 may be formed by a screen printing process. According to embodiments, the second protective layer 251 may include at least one of gold (Au) and silver (Ag).

A thickness T1′ of the second protective layer 251 formed by the screen printing process may be greater than the thickness T1 of the second protective layer 250 formed by the electroless plating process as described with reference to FIG. 4A and FIG. 4B. According to some embodiments, the thickness of the second protective layer 251 may be in a range from about 50 μm to about 100 μm. Also, the second protective layer 251 formed by the screen printing process may be on and cover only the upper surface of the first protective layer 230 and may not be on or cover the side surfaces of the first protective layer 230. That is, the side surfaces of the first protective layer 230 may, in some embodiments, be free of the second protective layer 251. In some embodiments, the second protective layer 251 may on and cover the upper surface of the first protective layer 230 and may be on and cover at least a portion of the side surfaces of the first protective layer 230.

The third protective layer 270 may be located on the second protective layer 251. According to some embodiments, the third protective layer 270 may be on and completely cover the upper surface of the second protective layer 251. The upper surface of the second protective layer 251 may be opposite to the lower surface of the second protective layer 251. Also, the lower surface of the second protective layer 251 may be a surface of the second protective layer 251, which is in contact with the first protective layer 230. According to some embodiments, the third protective layer 270 may be formed by the screen printing process.

According to embodiments, the third protective layer 270 may include solder or silver (Ag). Because the third protective layer 270 is formed by the screen printing process, the third protective layer 270 may be on and cover only the upper surface of the second protective layer 251 and may not be on or cover side surfaces of the second protective layer 251, as shown in FIGS. 6A and 6B. That is, the side surfaces of the second protective layer 251 may, in some embodiments, be free of the third protective layer 270. In some embodiments, the third protective layer 270 may not be on or cover at least a portion of a side surface of the second protective layer 251. In this case, the third protective layer 270 may be on and partially cover the side surfaces of the second protective layer 251, but not be on and completely cover the side surfaces of the second protective layer 251. A thickness T2, in the vertical direction Z, of the third protective layer 270 formed by the screen printing process may be in a range from about 50 μm to about 100 μm.

In the printed circuit boards 102 and 102-1 according to the inventive concept, the second protective layer 251 and the third protective layer 270 are formed by the screen printing method. Accordingly, the second protective layer 251 and the third protective layer 270 may each have an increased thickness. Because each of the second protective layer 251 and the third protective layer 270 is formed by the screen printing process, corrosion of the lower pad 210 may be prevented or inhibited more effectively than when each of the second protective layer 251 and the third protective layer 270 is formed by the electroless plating process.

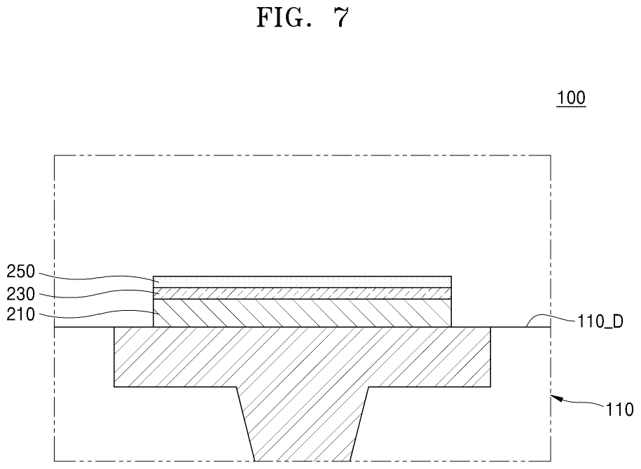

FIGS. 7 to 12 are enlarged views illustrating a method of manufacturing a connector of a printed circuit board 100, according to an embodiment. Hereinafter, repeated descriptions as those given with reference to FIGS. 1, 2A, 2B, 3, 4A, 4B, 5A, 5B, 6A, and 6B are omitted, and the description focuses on the differences in the embodiments.

Referring to FIG. 7, a lower pad 210 is formed on a lower surface 110_D of a body 110, and then a first protective layer 230 and a second protective layer 250 are formed by an electroless plating process. The first protective layer 230 may be on and at least partially cover the lower pad 210, and the second protective layer 250 may be on and at least partially cover the first protective layer 230. In FIG. 7 and subsequent drawings, the first protective layer 230 is illustrated as being on and covering only the upper surface of the lower pad 210, and the second protective layer 250 is illustrated as being on and covering only the upper surface of the first protective layer 230. However, this is for convenience of illustration. The first protective layer 230 may, in some embodiments, be on and cover the side surfaces of the lower pad 210 as illustrated in FIGS. 4B, 5B, and 6C, and the second protective layer 250 may, in some embodiments, be on and cover the side surfaces of the first protective layer 230 as illustrated in FIG. 4B.

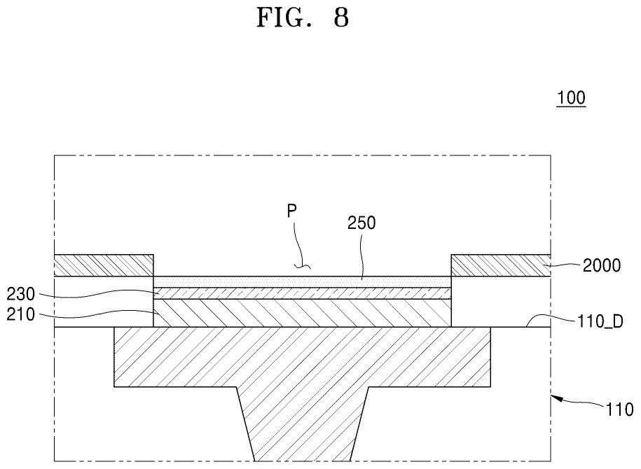

Referring to FIG. 8, a metal mask 2000 having a pattern P is disposed above the lower surface 110_D of the body 110. The pattern P may include a hole vertically extending through the metal mask 2000. In this case, the pattern P may be formed at substantially the same position as each of the lower pads 210 that are formed on the lower surface 110_D of the body 110. The metal mask 2000 may be located above the lower surface 110_D of the body 110, such that the pattern P overlaps the lower pad 210 in the vertical direction Z. In some embodiments, the metal mask 2000 may be spaced apart from the lower surface 110_D of the body 110 by a desired distance in the vertical direction Z. According to embodiments, the width of the pattern P may be substantially equal to the width of the lower pad 210. However, the width of the pattern P is not limited thereto, and the width of the pattern P may be greater or less than the width of the lower pad 210 in other embodiments.

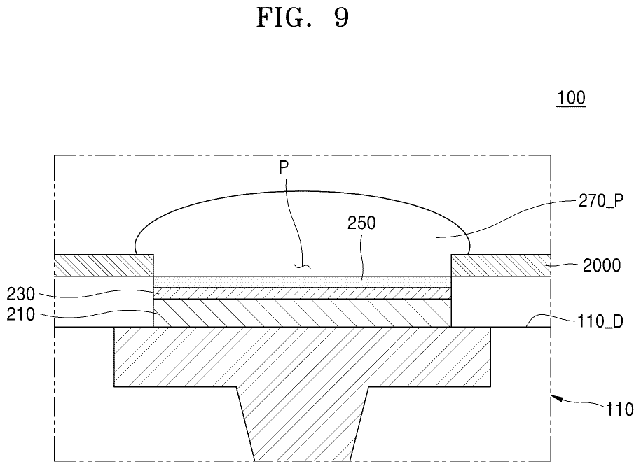

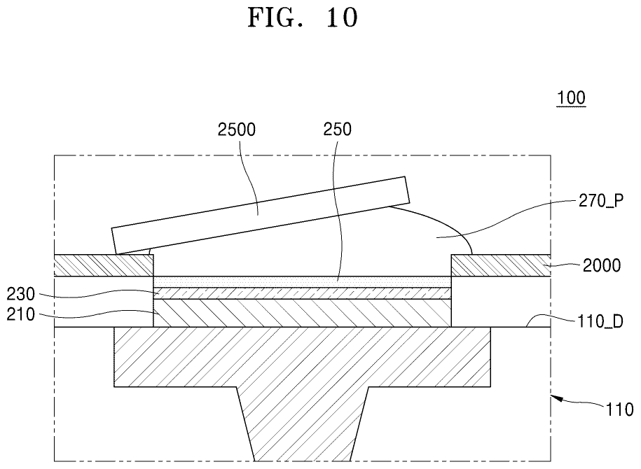

Referring to FIG. 9 and FIG. 10, solder paste 270_P is discharged into the pattern P of the metal mask 2000, and then the solder paste 270_P is pressed by a pressure bar 2500. Herein, the solder paste 270_P may be in full contact with the upper surface of the second protective layer 250. Also, the solder paste 270_P may not be in contact with the first protective layer 230 and spaced apart from the first protective layer 230 in the vertical direction Z.

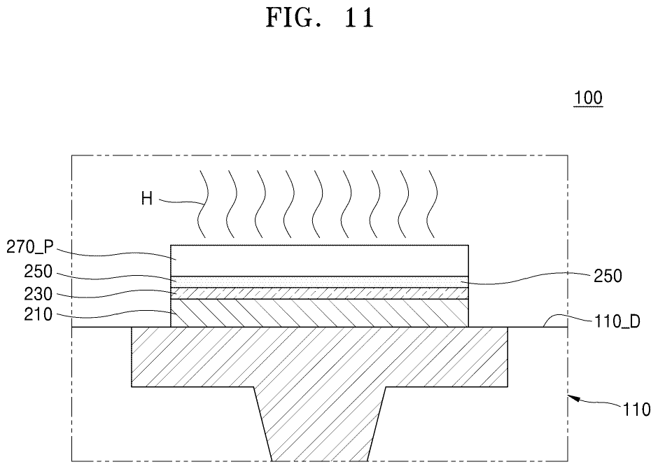

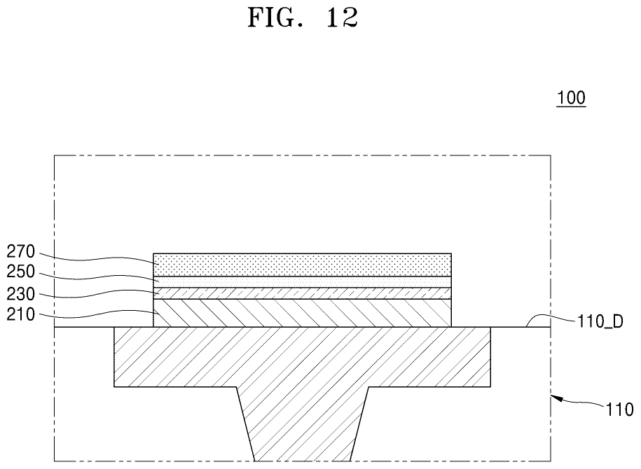

Referring to FIG. 11 and FIG. 12, the metal mask 2000 and the pressure bar 2500 are removed, and then a reflow process is performed in which heat H is applied to the solder paste 270_P. Through the reflow process, the solder paste 270_P may be uniformly distributed and cured on the upper surface of the second protective layer 250. As a result, a third protective layer 270 on and at least partially covering the second protective layer 250 may be formed. The third protective layer 270 formed by the screen printing process may have a greater thickness than each of the first protective layer 230 and the second protective layer 250 in the vertical direction Z.

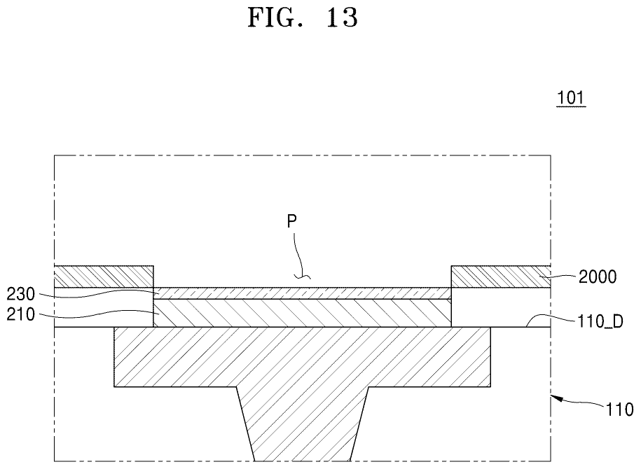

FIGS. 13 to 17 are enlarged views illustrating a method of manufacturing a connector of a printed circuit board 101, according to an embodiment. Hereinafter, repeated descriptions as those given with reference to FIGS. 1, 2A, 2B, 3, 4A, 4B, 5A, 5B, 6A, and 7 to 12 are omitted, and the description focuses on the differences in the embodiments.

Referring to FIG. 13, a lower pad 210 is formed on a lower surface 110_D of a body 110, and then a first protective layer 230 is formed by an electroless plating process. The first protective layer 230 may on and at least partially cover the lower pad 210. In FIG. 13 and subsequent figures, the first protective layer 230 is illustrated as being on and covering only the upper surface of the lower pad 210. However, this is for convenience of illustration. The first protective layer 230 may, in some embodiments, be on and cover the side surfaces of the lower pad 210 as illustrated in FIGS. 4B, 5B, and 6C. Subsequently, a metal mask 2000 having a pattern P is disposed above the lower surface 110_D of the body 110. The pattern P may include a hole vertically extending through the metal mask 2000. In this case, the pattern P may be formed at substantially the same position as each of the lower pads 210 that are formed on the lower surface 110_D of the body 110. The metal mask 2000 may be located above the lower surface 110_D of the body 110 such that the pattern P overlaps the lower pad 210 in the vertical direction Z.

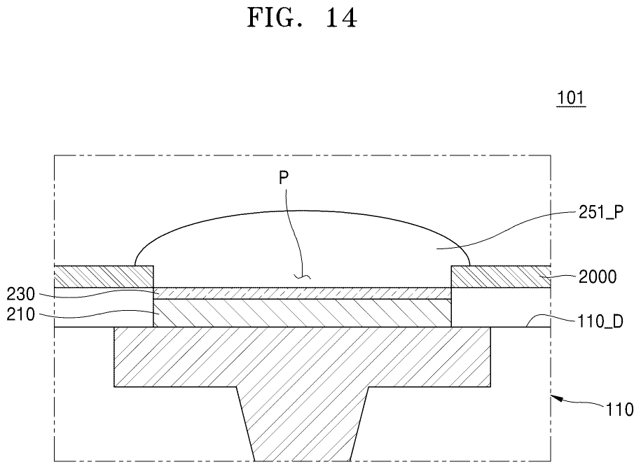

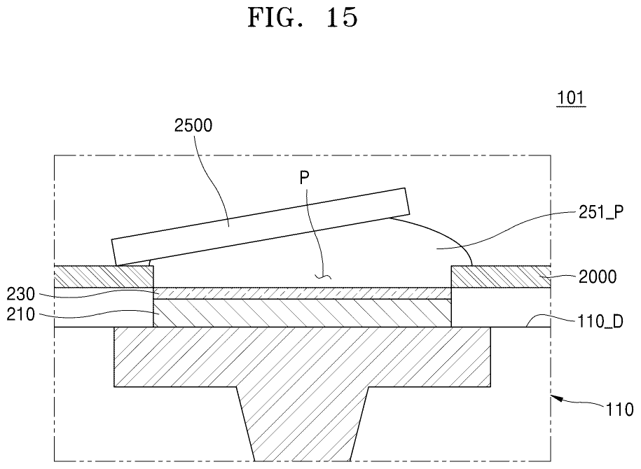

Referring to FIG. 14 and FIG. 15, gold (Au) paste 251_P is discharged into the pattern P of the metal mask 2000, and then the gold paste 251_P is pressed by a pressure bar 2500. Herein, the gold paste 251_P may be in full contact with the upper surface of the first protective layer 230. Also, the gold paste 251_P may not be in contact with the lower pad 210.

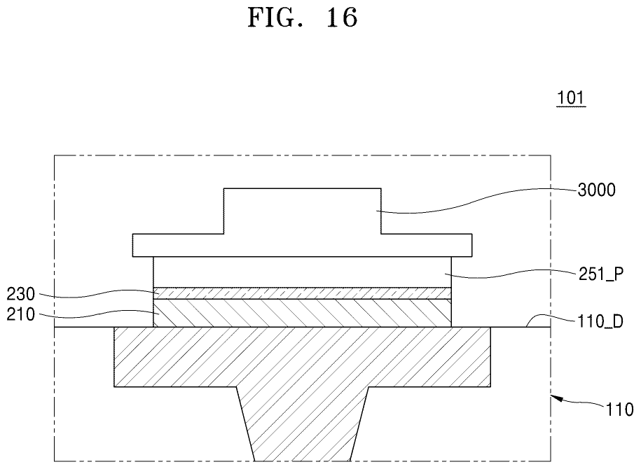

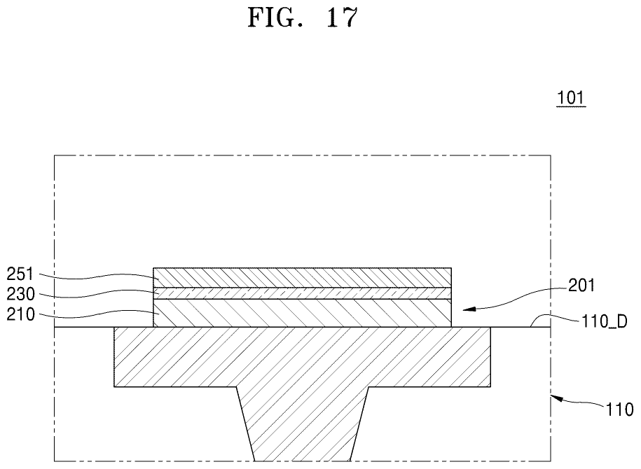

Referring to FIGS. 16 and 17, the metal mask 2000 and the pressure bar 2500 are removed, and then a sintering process is performed on the resultant product. The gold paste 251_P may be uniformly distributed on the upper surface of the first protective layer 230 by a sintering process, that is, applying pressure and heat to the gold paste 251_P using a pressure member 3000. The second protective layer 251 formed by the processes described above may have a greater thickness than the first protective layer 230 in the vertical direction Z.

While embodiments of the inventive concept have been particularly shown and described with reference to embodiments thereof, it will be understood that various changes in form and details may be made therein without departing from the spirit and scope of the following claims.

What is claimed is:

1. A printed circuit board comprising:
a body comprising a wiring pattern and an insulating layer at least partially surrounding the wiring pattern; and
a connector on a lower surface of the body,
wherein the connector comprises:
a lower pad located on the lower surface of the body; and
a plurality of protective layers on the lower pad where one of the protective layers comprises solder.

2. The printed circuit board of claim 1, wherein the plurality of protective layers comprises:
a first protective layer on the lower pad;
a second protective layer on the first protective layer; and
a third protective layer on the second proactive layer,
wherein the first protective layer and the second protective layer are formed by electroless plating, and
wherein the third protective layer comprises the solder and is formed by a screen printing process.

3. The printed circuit board of claim 2, wherein the first protective layer is configured to at least partially cover an upper surface and side surface of the lower pad, and
wherein the second protective layer is configured to at least partially cover an upper surface and side surface of the first protective layer.

4. The printed circuit board of claim 3, wherein a thickness of the third protective layer in a first direction is greater than a thickness of the second protective layer in the first direction, the first direction being perpendicular to the lower surface of the body, and
wherein the thickness of the third protective layer in the first direction is in a range from about 50 μm to about 100 μm.

5. The printed circuit board of claim 3, wherein the third protective layer is configured to at least partially cover an upper surface of the second protective layer, and
wherein at least a portion of a side surface of the second protective layer is free of the third protective layer.

6. The printed circuit board of claim 2, wherein the first protective layer is formed by electroless plating, and
wherein the second protective layer is formed by a screen printing process.

7. The printed circuit board of claim 6, wherein the first protective layer is configured to at least partially cover an upper surface and side surface of the lower pad,
wherein the second protective layer is configured to at least partially cover an upper surface of the first protective layer,
wherein at least a portion of a side surface of the first protective layer is free of the second protective layer,
wherein the third protective layer is configured to at least partially cover an upper surface of the second protective layer, and
wherein at least a portion of a side surface of the second protective layer is free of the third protective layer.

8. The printed circuit board of claim 1, wherein the body further comprises a hole extending through the body from an upper surface of the body to the lower surface of the body, and
wherein the body is screw-fastened to a motherboard via the hole in the body.

9. The printed circuit board of claim 1, further comprising an upper pad located on an upper surface of the body opposite to the lower surface of the body,
wherein the upper pad is electrically connected to a semiconductor chip, and
wherein the connector is configured to electrically connect the body to a motherboard.

10. The printed circuit board of claim 9, wherein the semiconductor chip comprises a memory chip.

11. A printed circuit board comprising:
a body comprising a wiring pattern and an insulating layer configured to at least partially cover the wiring pattern; and
a connector on a lower surface of the body,
wherein the connector comprises:
a lower pad on the lower surface of the body;
a first protective layer on the lower pad and comprising nickel; and
a second protective layer on the first protective layer,
wherein the second protective layer is formed by a screen printing process, and
wherein a thickness of the second protective layer in a first direction is greater than a thickness of the first protective layer in the first direction, the first direction being perpendicular to the lower surface of the body.

12. The printed circuit board of claim 11, wherein the second protective layer comprises at least one of gold (Au) and silver (Ag).

13. The printed circuit board of claim 11, wherein the first protective layer is formed by electroless plating and configured to at least partially cover an upper surface and side surface of the lower pad.

14. The printed circuit board of claim 13, wherein the second protective layer is configured to cover an upper surface of the first protective layer, and
wherein at least a portion of a side surface of the first protective layer is free of the second protective layer.

15. The printed circuit board of claim 11, wherein the thickness of the second protective layer in the first direction is in a range from about 50 μm to about 100 μm.

16. The printed circuit board of claim 11, further comprising an upper pad on an upper surface of the body opposite to the lower surface of the body,
wherein the upper pad is electrically connected to a semiconductor chip,
wherein the connector is configured to electrically connect the body to a motherboard,
wherein the body further comprises a hole extending through the body from the upper surface of the body to the lower surface of the body, and
wherein the body is screw-fastened to the motherboard via the hole in the body.

17. The printed circuit board of claim 11, wherein the insulating layer comprises at least one material selected from a group consisting of phenolic resin, epoxy resin, and polyimide, and
wherein the wiring pattern comprises at least one material selected from a group consisting of copper, nickel, stainless steel, and beryllium copper.

18. A semiconductor package comprising:
a body comprising a wiring pattern, an insulating layer at least partially surrounding the wiring pattern, and a hole extending through the body in a first direction from an upper surface of the body to a lower surface of the body;
a connector on the lower surface of the body;
an upper pad on the upper surface of the body; and
a semiconductor chip electrically connected to the body via the upper pad,
wherein the connector comprises:
a lower pad on the lower surface of the body;
a first protective layer on the lower pad;
a second protective layer on the first protective layer; and
a third protective layer located on the second protective layer,
wherein the first protective layer comprises nickel and is formed by an electroless plating process,
wherein the second protective layer comprises silver,
wherein the third protective layer is formed by a screen printing process,
wherein the third protective layer comprises at least one of solder and silver,
wherein a thickness of the third protective layer is greater than a thickness of the first protective layer, and
wherein the thickness of the third protective layer in the first direction is in a range from about 50 μm to about 100 μm.

19. The semiconductor package of claim 18, wherein a plurality of semiconductor chips are mounted on the upper surface of the body, and
wherein at least one of the plurality of semiconductor chips comprises a memory chip.

20. The semiconductor package of claim 18, wherein the second protective layer is formed by a screen printing process,
wherein the first protective layer is configured to at least partially cover an upper surface and side surface of the lower pad,
wherein the second protective layer is configured to at least partially cover an upper surface of the first protective layer,
wherein at least a portion of a side surface of the first protective layer is free of the second protective layer,
wherein the third protective layer is configured to at least partially cover an upper surface of the second protective layer, and
wherein at least a portion of a side surface of the second protective layer is free of the third protective layer.
